(19) United States
(12) Patent Application Publication
(10) Pub. No.: US 2024/0155763 A1
(43) Pub. Date: May 9, 2024

(54) Flexible Printed Wiring Board and Method for Manufacturing Same

(71) Applicant: Nippon Mektron, Ltd., Tokyo-to (JP)

(72) Inventor: Yoshihiko Narisawa, Tokyo-to (JP)

(21) Appl. No.: 18/501,237

(22) Filed: Nov. 3, 2023

(30) Foreign Application Priority Data
Nov. 4, 2022 (JP) 2022-177636

(51) Int. Cl. H05K 1/02; H05K 3/46

(52) U.S. Cl. CPC H05K 1/028; H05K 3/4658; H05K 2201/0355; H05K 2201/093

(57) ABSTRACT

A flexible printed wiring board according to an embodiment is a flexible printed wiring board having a bent region provided with air layers, including a signal line passing through the bent region; and ground layers provided in a layer different from the signal line via an insulating layer, in which the ground layers are not provided in at least a part of a portion overlapping the signal line in the bent region when the flexible printed wiring board is viewed in a thickness direction.

### BACKGROUND OF THE INVENTION

### Field of the Invention

The present invention relates to a flexible printed wiring board and a method for manufacturing the same, and more particularly to a flexible printed wiring board having a bent region and a method for manufacturing the same.

### Background Art

In recent years, with an increase in a signal transmission speed in an electronic device, wiring for performing high-speed signal transmission such as a thin wire coaxial cable is often used. In a case where transmission of a plurality of high-speed transmission signals is necessary, replacement with a printed wiring board that can easily perform wiring in a device in a more space-saving manner is in progress. For example, Japanese Patent No. 6732723 describes a flexible printed wiring board (flexible printed wiring board) provided with high-speed signal transmission wiring for transmitting a high-speed signal.

In a case where the flexible printed wiring board is disposed on a folding portion (a hinge or the like) of a housing of an electronic device, the flexible printed wiring board needs to have sufficient bending resistance. However, in a case of a flexible printed wiring board having two or more conductor layers, stress generated in the conductor layer at the time of bending is large, and thus the risk of disconnection of the conductor layer due to metal fatigue increases. In order to avoid this, it is known that a hollow portion (air layer) is provided between the conductor layers in a bent region to greatly alleviate the stress applied to the conductor layer at the time of bending.

### CITATION LIST

### Patent Literature

Patent Literature 1: Japanese Patent No. 6732723
Patent Literature 2: Japanese Patent No. 4236837
Patent Literature 3: Japanese Patent No. 4481184

### SUMMARY OF THE INVENTION

Meanwhile, in order to suppress deterioration of signal quality due to reflection of a high-speed signal, it is necessary to match a characteristic impedance to a predetermined value (target value) over the entire hollow portion and non-hollow portion of the flexible printed wiring board. For example, assuming transmission of a signal received by an antenna, in order to suppress the deterioration of the signal quality, it is desirable to keep a change in the characteristic impedance accompanying bending of the flexible printed wiring board within ±10% of the target value. In a case of a transmission line system including a single-ended 50Ω, the characteristic impedance is preferably matched within a range of 50±5Ω.

However, in the flexible printed wiring board in the related art, it is difficult to keep the characteristic impedance within the range. This is because, when the flexible printed wiring board is bent, a distance between a signal line and a ground layer varies in the hollow portion, and accordingly, a capacitance component between the signal line and the ground layer varies, resulting in variation in the characteristic impedance.

The present invention has been made based on the above recognition, and an object of the present invention is to provide a flexible printed wiring board capable of suppressing variation in a characteristic impedance when a flexible printed wiring board is bent, and a method for manufacturing the same.

A flexible printed wiring board according to an embodiment is
a flexible printed wiring board having a bent region provided with an air layer including
a signal line passing through the bent region; and a ground layer provided in a layer different from the signal line via an insulating layer, in which
the ground layer is not provided in at least a part of a portion overlapping the signal line when the flexible printed wiring board is viewed in a thickness direction in the bent region.

Further, in the flexible printed wiring board,
the ground layer may be provided with a ground opening at least partially overlapping the signal line when the flexible printed wiring board is viewed in the thickness direction.

Further, in the flexible printed wiring board,
a width of the ground opening may be equal to a width of the signal line.

Further, the flexible printed wiring board may further include,
guard ground wirings provided so as to sandwich the signal line, and
the ground opening may be opened up to a side end portion of the guard ground wiring on a side facing the signal line when the flexible printed wiring board is viewed in the thickness direction.

Further, the flexible printed wiring board may further include,
guard ground wirings provided so as to sandwich the signal line, and
the ground opening may be opened up to a middle of the guard ground wiring when the flexible printed wiring board is viewed in the thickness direction.

Further, in the flexible printed wiring board,
a plurality of the signal lines are provided so as to run in parallel, and
the ground opening may be opened such that at least a part of the ground opening overlaps the plurality of signal lines when the flexible printed wiring board is viewed in the thickness direction.

Further, in the flexible printed wiring board,
the ground opening may be opened up to a position 50 to 100 μm away from the side end portion of the signal line in the width direction of the signal line.

Further, in the flexible printed wiring board,
the ground layer may have a first ground layer and a second ground layer sandwiching the bent region.

A method for manufacturing a flexible printed wiring board according to an embodiment includes:
preparing a first single-sided metal clad laminated board having a first base film and a first metal foil provided on one main surface of the first base film;
patterning the first metal foil of the first single-sided metal clad laminated board to form a signal line;
preparing a cover lay having a cover film and a first adhesive layer provided on one main surface of the cover film, and bonding the cover lay to the first base film such that the first adhesive layer buries the signal line;
temporarily attaching a first bonding sheet provided with a first through region onto the cover film, and temporarily attaching a second bonding sheet provided with a second through region onto the first base film;
preparing a second single-sided metal clad laminated board having a second base film and a second metal foil provided on one main surface of the second base film, and bonding the second single-sided metal clad laminated board to the first bonding sheet such that the second base film is in contact with the first bonding sheet;
preparing a third single-sided metal clad laminated board having a third base film and a third metal foil provided on one main surface of the third base film, and bonding the third single-sided metal clad laminated board to the second bonding sheet such that the third base film is in contact with the second bonding sheet;
forming a conformal mask for laser processing on the second metal foil;
irradiating the conformal mask with laser light to form a conductive hole in which the signal line is exposed on a bottom surface;
performing plating processing on the conductive hole to form a via electrically coupling the signal line and the second metal foil; and
patterning the second metal foil to form a signal terminal electrically coupled to the via and a ground layer that is not provided in at least a part of a portion overlapping the signal line as viewed in a thickness direction in the first through region.

Further, the method for manufacturing a flexible printed wiring board may further include,
patterning the third metal foil to form a second ground layer that is not provided in at least the part of the portion overlapping the signal line as viewed in the thickness direction in the second through region.

According to the present invention, it is possible to provide a flexible printed wiring board capable of suppressing variation in a characteristic impedance when the flexible printed wiring board is bent, and a method for manufacturing the same.

### BRIEF DESCRIPTION OF THE DRAWINGS

FIG. 1A is a process cross-sectional view illustrating a method for manufacturing a flexible printed wiring board according to an embodiment;

FIG. 1B is a process cross-sectional view for explaining the method for manufacturing a flexible printed wiring board according to the embodiment, following FIG. 1A;

FIG. 1C is a process cross-sectional view for explaining the method for manufacturing a flexible printed wiring board according to the embodiment, following FIG. 1B;

FIG. 2 is a plan view of the flexible printed wiring board according to the embodiment;

FIG. 3A is a cross-sectional view taken along line I-I in FIG. 2;

FIG. 3B is a cross-sectional view taken along line II-II in FIG. 2;

FIG. 4 is a diagram illustrating a simulation result of a transmission characteristic (characteristic impedance) of the flexible printed wiring board according to the embodiment;

FIG. 5 is a plan view of a flexible printed wiring board according to a first modification of the embodiment;

FIG. 6 is a cross-sectional view taken along line II-II in FIG. 5;

FIG. 7 is a diagram illustrating a simulation result of a transmission characteristic (characteristic impedance) of the flexible printed wiring board according to the first modification of the embodiment;

FIG. 8 is a plan view of a flexible printed wiring board according to a second modification of the embodiment;

FIG. 9 is a cross-sectional view taken along line II-II in FIG. 8;

FIG. 10 is a diagram illustrating a simulation result of a transmission characteristic (characteristic impedance) of the flexible printed wiring board according to the second modification of the embodiment;

FIG. 11A is a plan view of a flexible printed wiring board according to a comparative example;

FIG. 11B is a cross-sectional view taken along line I-I in FIG. 11A; and

FIG. 12 is a diagram illustrating a simulation result of a transmission characteristic (characteristic impedance) of the flexible printed wiring board according to the comparative example.

### DETAILED DESCRIPTION OF THE INVENTION

Hereinafter, an embodiment according to the present invention will be described with reference to the drawings. Note that, in each drawing, components having equivalent functions are denoted by the same reference numerals. In addition, the drawings are schematic and mainly illustrate the characteristic portions according to each embodiment, and a relationship between a thickness and a plane dimension, a ratio of a thickness of each layer, and the like are different from actual ones.

<Method for Manufacturing Flexible Printed Wiring Board>

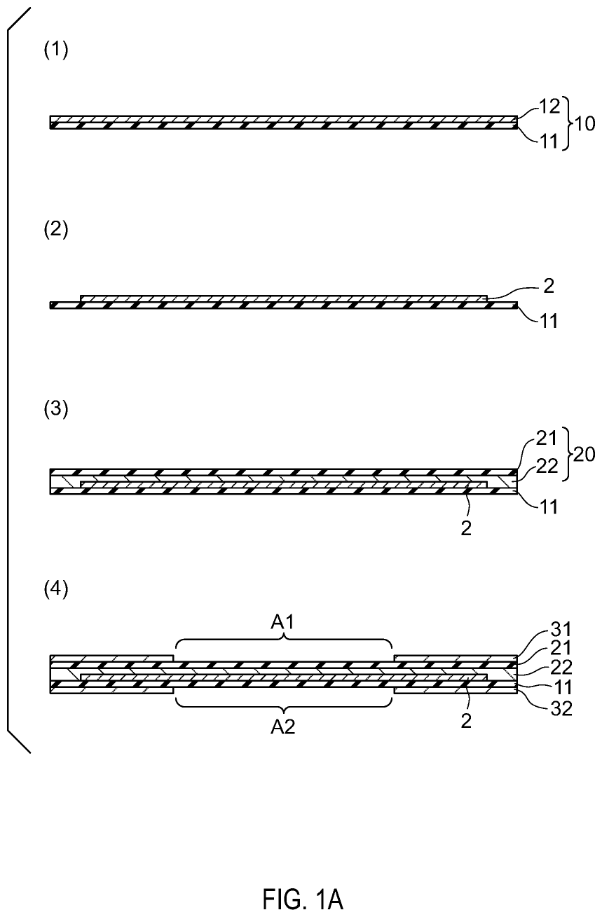

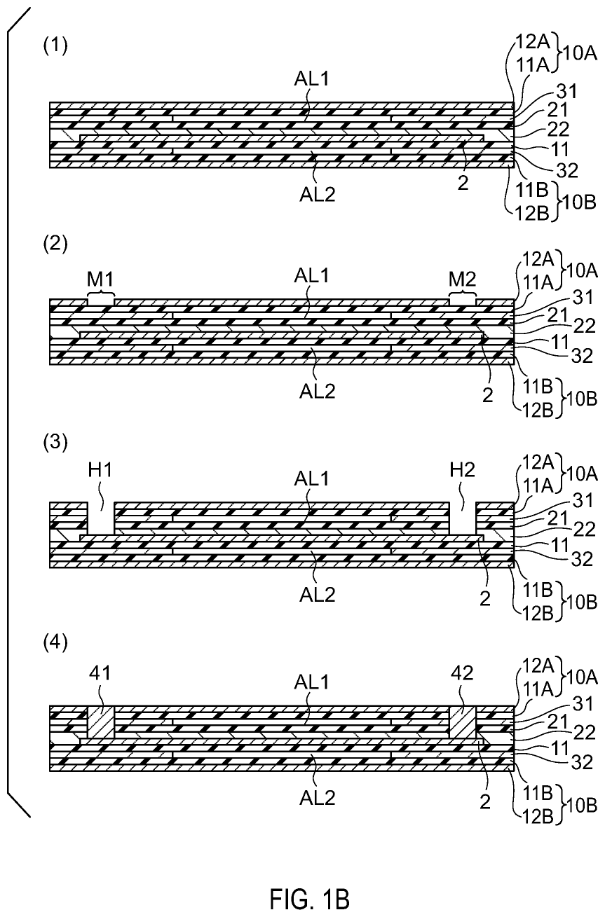

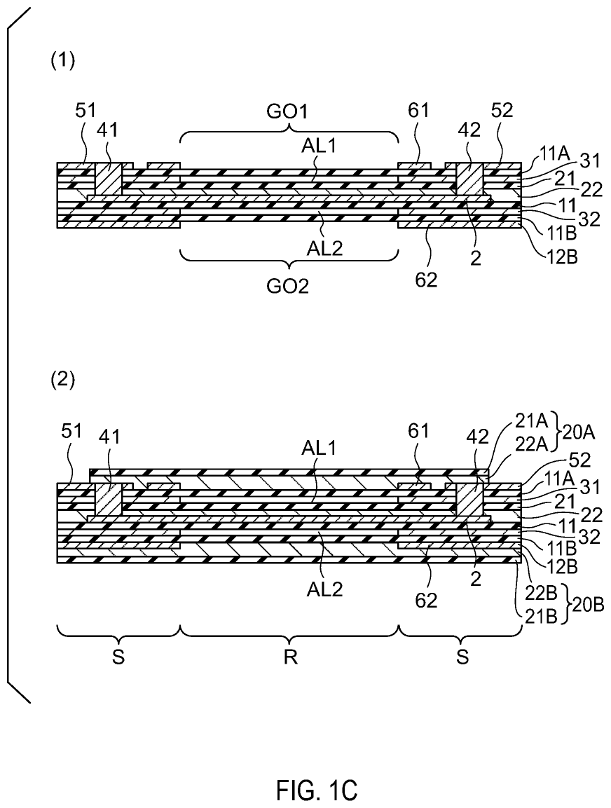

First, a method for manufacturing a flexible printed wiring board according to an embodiment will be described with reference to process cross-sectional views of FIGS. 1A to 1C.

As illustrated in (1) of FIG. 1A, a single-sided metal clad laminated board 10 having a base film 11 (first base film) and a metal foil 12 (first metal foil) provided on one main surface of the base film 11 is prepared. The base film 11 is an insulating film made of polyimide or the like. The metal foil 12 is a copper foil.

Next, as illustrated in (2) of FIG. 1A, the metal foil 12 of the single-sided metal clad laminated board 10 is patterned by using a technique such as photofabrication to form a signal line 2. In this process, a guard ground wiring 3 to be described later is also formed.

Next, as illustrated in (3) of FIG. 1A, a cover lay 20 having a cover film 21 and an adhesive layer 22 provided on one main surface of the cover film 21 is prepared, and the cover lay 20 is bonded to the base film 11 such that the adhesive layer 22 buries the signal line 2.

Next, as illustrated in (4) of FIG. 1A, a bonding sheet 31 provided with a through region A1 is temporarily attached onto the cover film 21. Similarly, a bonding sheet 32 provided with a through region A2 is temporarily attached onto the base film 11. The bonding sheets 31 and 32 are made of, for example, the same material as the adhesive layer 22.

Through the punching or the like, the through regions A1 and A2 are provided in the bonding sheets 31 and 32, respectively.

In the present embodiment, the bonding sheets 31 and 32 are disposed such that the through region A1 and the through region A2 substantially overlap each other when viewed in a thickness direction. The through regions A1 and A2 serve as air layers (hollow portions), and serve as a bent region R (described later) of the flexible printed wiring board according to the embodiment. The bonding sheets 31 and 32 may be disposed such that the through region A1 and the through region A2 partially overlap each other when viewed in the thickness direction.

Next, as illustrated in (1) of FIG. 1B, a single-sided metal clad laminated board 10A having a base film 11A and a metal foil 12A provided on one main surface of the base film 11A is prepared. The base film 11A is an insulating film made of polyimide or the like, and the metal foil 12A is a copper foil. The single-sided metal clad laminated board 10A is bonded to the bonding sheet 31 such that the base film 11A is in contact with the bonding sheet 31.

Similarly, a single-sided metal clad laminated board 10B having a base film 11B and a metal foil 12B provided on one main surface of the base film 11B is prepared. The base film 11B is an insulating film made of polyimide or the like, and the metal foil 12B is a copper foil. The single-sided metal clad laminated board 10B is bonded to the bonding sheet 32 such that the base film 11B is in contact with the bonding sheet 32.

As described above, the single-sided metal clad laminated board 10A and the single-sided metal clad laminated board 10B are bonded to the bonding sheet 31 and the bonding sheet 32, respectively, and then the adhesive layer 22 and the bonding sheets 31 and 32 are cured by heating and pressurizing by using a vacuum press apparatus or a vacuum laminator apparatus.

Next, as illustrated in (2) of FIG. 1B, conformal masks M1 and M2 for laser processing are formed on the metal foil 12A. The conformal masks M1 and M2 are formed, for example, by performing etching processing on the metal foil 12A. In the present embodiment, the conformal masks M1 and M2 are formed in portions corresponding to both end portions (left end and right end in (2) of FIG. 1B) of the signal line 2.

Next, as illustrated in (3) of FIG. 1B, the conformal masks M1 and M2 are irradiated with laser light to form conductive holes H1 and H2 in which the signal line 2 is exposed on a bottom surface. As the laser light, for example, an infrared laser such as a carbon dioxide laser or a UV-YAG laser is used. After the laser light is emitted, desmear processing is performed to remove resin residues and the like at bottom portions of the conductive holes H1 and H2.

Next, as illustrated in (4) of FIG. 1B, the conductive holes H1 and H2 are subjected to plating processing (for example, electrolytic copper plating processing) to form vias 41 and 42 that electrically couple the signal line 2 and the metal foil 12A. In the present embodiment, the conductive holes H1 and H2 are filled with a plating metal (for example, copper), but may not be filled.

Next, as illustrated in (1) of FIG. 1C, the metal foil 12A is patterned by using a technique such as photofabrication to form signal terminals 51 and 52 electrically coupled to the vias 41 and 42. In this process, a ground layer 61 electrically coupled to the guard ground wiring and provided with a ground opening GO1 is also formed. As will be described in detail later, the ground opening GO1 is formed so as to overlap the signal line 2 in the bent region R as viewed in the thickness direction.

As illustrated in (1) of FIG. 1C, the metal foil 12B is patterned to form a ground layer 62 provided with a ground opening GO2. Although not illustrated, the guard ground wiring 3 is electrically coupled to the ground layer 62 in an extension region S.

In the present embodiment, the ground opening GO1 and the ground opening GO2 are provided so as to overlap each other when viewed in the thickness direction.

Thereafter, as illustrated in (2) of FIG. 1C, cover lays 20A and 20B for protection are bonded. Specifically, the cover lay 20A having a cover film 21A and an adhesive layer 22A provided on one main surface of the cover film 21A is prepared, and the cover lay 20A is bonded such that the adhesive layer 22A buries the vias 41 and 42 and the ground opening GO1.

In addition, the cover lay 20B having a cover film 21B and an adhesive layer 22B provided on one main surface of the cover film 21B is prepared, and the cover lay 20B is bonded such that the adhesive layer 22B buries the ground opening GO2. Thereafter, the adhesive layers 22A and 22B are cured by heating and pressurization by using a vacuum press apparatus or a vacuum laminator apparatus.

After the above processes, the flexible printed wiring board 1 according to the embodiment is produced by performing surface processing on the signal terminals 51 and 52, outer shape processing, and the like. In the present embodiment, since unnecessary end portions are removed in the outer shape processing, the air layers penetrate the flexible printed wiring board 1 when viewed in the width direction of the signal line 2. According to the above manufacturing method, the ground opening GO1 can be formed in the process of forming the signal terminals 51 and 52. That is, the flexible printed wiring board 1 according to the embodiment can be manufactured without adding a new process.

The materials of the base films 11, 11A, and 11B and the cover film 21 may be polyimide-based materials such as MPI or PI, or other insulating materials such as a liquid crystal polymer (LCP) or a fluorine-based material (PFA, PTFE, or the like). The metal foils 12, 12A, and 12B may be metal foils made of metals (silver, aluminum, or the like) other than copper.

<Flexible Printed Wiring Board>

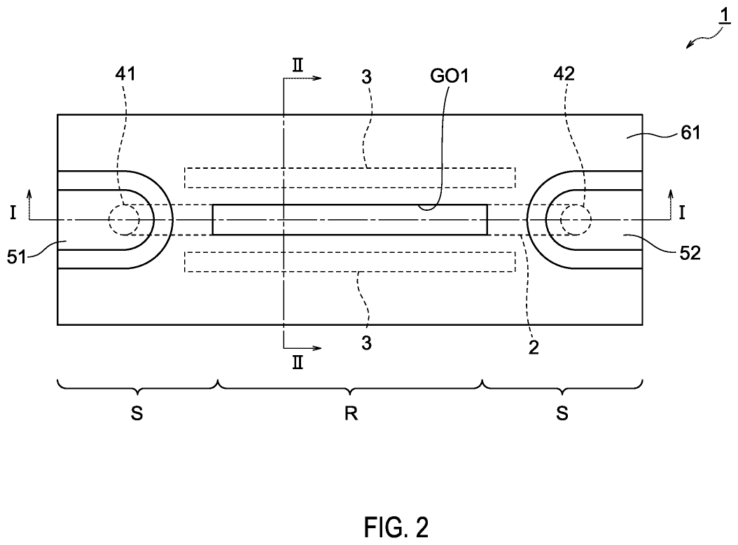

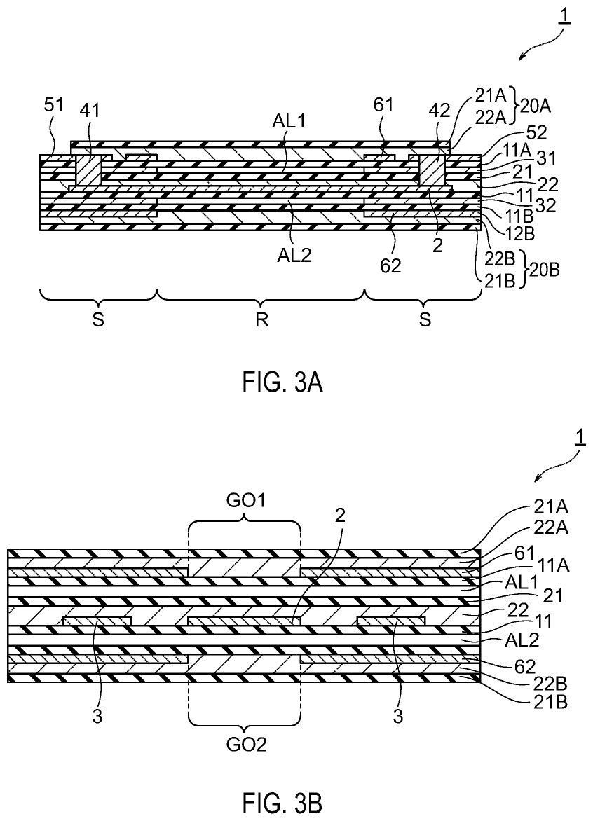

Next, the configuration of the flexible printed wiring board produced as described above will be described with reference to FIGS. 2 and 3. FIG. 2 is a plan view of the flexible printed wiring board according to the present embodiment. FIG. 3A is a cross-sectional view taken along line I-I in FIG. 2, and FIG. 3B is a cross-sectional view taken along line II-II in FIG. 2. FIG. 3B is the same as (2) of FIG. 1C.

The flexible printed wiring board 1 according to the present embodiment includes a signal line 2, a guard ground wiring 3, vias 41 and 42, signal terminals 51 and 52, and ground layers 61 and 62.

In the flexible printed wiring board 1, a region where the air layers AL1 and AL2 are provided between the signal line 2 and the ground layers 61 and 62 is a bent region R. The air layers AL1 and AL2 penetrate the flexible printed wiring board 1 when viewed in the width direction of the signal line 2. Since the air layers AL1 and AL2 are provided, the signal line 2, the ground layer 61, and the ground layer 62 can be bent independently. As a result, a stress generated by a difference in a radius of curvature at the time of bending is alleviated, so that high bending resistance can be obtained. Further, the air layers AL1 and AL2 extend from one side surface to the other side surface of the flexible printed wiring board 1. As a result, the bending resistance (repeated bending property) of the flexible printed wiring board 1 can be further improved.

The extension regions S in which the signal line 2 extends are provided so as to sandwich the bent region R. FIG. 2 illustrates a form in which the bent region R is longer than the extension region S. The present invention is not limited thereto, and the extension region S may be a region longer than the bent region R.

As illustrated in FIG. 3A, in the extension region S, the signal line 2 and the ground layer 61 are provided so as to sandwich an insulating layer including the adhesive layer 22, the cover film 21, the bonding sheet 31, and the base film 11A. In the bent region R, the signal line 2 and the ground layer 61 are provided so as to sandwich an insulating layer including the adhesive layer 22, the cover film 21, the air layer AL1, and the base film 11A.

In the extension region S, the signal line 2 and the ground layer 62 are provided so as to sandwich an insulating layer including the base film 11, the bonding sheet 32, and the base film 11B. In the bent region R, the signal line 2 and the ground layer 62 are provided so as to sandwich an insulating layer including the base film 11, the air layer AL2, and the base film 11B.

The signal line 2 is a line through which a high-frequency signal propagates. In the present embodiment, the signal line 2 is provided to extend through the bent region R along a longitudinal direction of the flexible printed wiring board 1. The flexible printed wiring board 1 has a so-called stripline structure in which the ground layer 61 and the ground layer 62 are provided on an upper side and a lower side of the signal line 1, respectively.

As illustrated in FIGS. 2 and 3B, the guard ground wirings 3 are provided so as to sandwich the signal line 2 in plan view. In the present embodiment, the guard ground wiring 3 is provided so as to extend through the bent region R along the longitudinal direction of the flexible printed wiring board 1. The guard ground wiring 3 is electrically coupled to the ground layer 61 and/or the ground layer 62 by a via (not illustrated) in the extension region S.

Note that the plurality of signal lines 2 may be provided so as to run in parallel. In this case, the guard ground wiring 3 is provided between the signal lines 2. Alternatively, the guard ground wiring 3 may be provided so as to sandwich the plurality of signal lines 2.

The via 41 electrically couples one end of the signal line 2 and the signal terminal 51. The via 42 electrically couples the other end of the signal line 2 and the signal terminal 52. The signal terminals 51 and 52 are coupled to a connector, another printed wiring board, or the like.

The ground layers 61 and 62 are provided in a layer different from the signal line 2 via the insulating layer as described above. The ground layers 61 and 62 preferably form a so-called solid pattern on a proximity surface that comes close to another component or the printed wiring board when the flexible printed wiring board 1 is disposed in the housing of the electronic device. The ground layers 61 and 62 may be in a solid pattern over the bent region R and the extension region S.

As illustrated in FIGS. 2 and 3B, in the ground layers 61 and 62, the ground openings GO1 and GO2 are provided so that the ground layers 61 and 62 do not overlap the signal line 2 in the bent region R when the flexible printed wiring board 1 is viewed in the thickness direction. That is, the ground layer 61 is provided with the ground opening GO1 overlapping the signal line 2 as viewed in the thickness direction, and the ground layer 62 is provided with the ground opening GO2 overlapping the signal line 2 as viewed in the thickness direction. In the present embodiment, as illustrated in FIG. 3B, the widths of the ground openings GO1 and GO2 are equal to the width of the signal line 2.

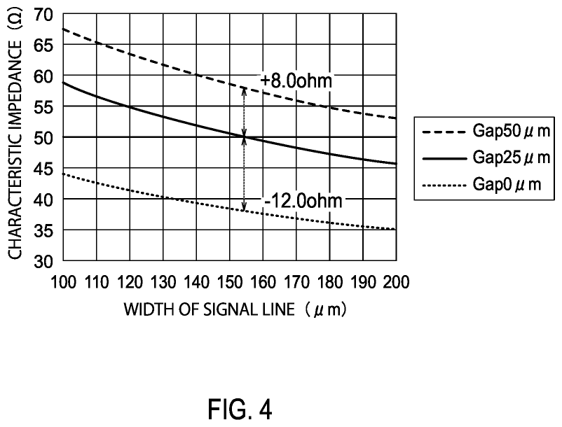

FIG. 4 illustrates a simulation result of a transmission characteristic (characteristic impedance) of the flexible printed wiring board 1 according to the present embodiment. A distance between the signal line 2 and the guard ground wiring 3 is set to 50 μm. A line width of the guard ground wiring 3 is set to be the same as that of the signal line 2. The thickness and physical properties of each layer used in the simulation are as indicated in Table 1.

TABLE 1

| | | | RELATIVE | DIELECTRIC |
|---|---|---|---|---|
| | | | DIELECTRIC | LOSS |
| LAYER | THICKNESS | | CONSTANT | TANGENT |
| COVER FILMS | 25 | μm | 3.1 | 0.015 |
| 21, 21A, AND 21B | | | | |
| ADHESIVE LAYERS | 25 | μm | 3.1 | 0.015 |
| 22, 22A, AND 22B | | | | |
| BONDING SHEETS | | | | |
| 31 AND 32 | | | | |
| GROUND LAYERS | 12 | μm | — | — |
| 61 AND 62 | | | | |
| BASE FILMS | 25 | μm | 3.2 | 0.003 |
| 11, 11A, AND 11B | | | | |
| AIR LAYERS | 0 | μm | 1 | 0 |
| AL1 AND AL2 | 25 | μm | | |
| | 50 | μm | | |
| SIGNAL LINE 2 | 12 | μm | — | — |
| GUARD GROUND | | | | |
| WIRING 3 | | | | |

According to the result of the simulation performed under the above conditions, 50Ω that is a target value of the characteristic impedance is achieved when the thicknesses (Gap) of the air layers AL1 and AL2 are each 25 μm (design value) and the line width of the signal line 2 is between 150 to 160 μm. When Gap is 0 μm, the characteristic impedance at the line width is 38Ω (−12.0Ω from the target value), and when Gap is 50 μm, the characteristic impedance at the line width is 58Ω (+8.0Ω from the target value). As described above, the characteristic impedance varies by ±10% or more from the target value with the change in the thickness of the air layers AL1 and AL2 due to the bending. However, the variation in the characteristic impedance can be reduced as compared with a case where the ground opening is not provided (comparative example described later).

Note that the ground openings GO1 and GO2 of the ground layers 61 and 62 may not be provided over the entire region of the bent region R in the longitudinal direction. That is, the ground openings GO1 and GO2 may be provided only in a partial region of the bent region R in the longitudinal direction.

In addition, the ground openings GO1 and GO2 may not be opened up to the side end portions of the signal line 2 over the entire region in the width direction orthogonal to the longitudinal direction of the flexible printed wiring board 1. That is, the ground openings GO1 and GO2 may be provided only in a partial region of the bent region R in the width direction.

In addition, the opening shapes of the ground opening GO1 and the ground opening GO2 may be different from each other.

When the plurality of signal lines 2 are provided, the ground openings GO1 and GO2 may be opened such that at least parts of the ground openings GO1 and GO2 overlap the plurality of signal lines 2 when the flexible printed wiring board 1 is viewed in the thickness direction.

Alternatively, for each signal line 2, the ground openings GO1 and GO2 overlapping at least a part of the corresponding signal line 2 may be provided.

Opening widths of the ground openings GO1 and GO2 are not limited to the above embodiment. First and second modifications in which the opening widths of the ground openings GO1 and GO2 are different will be described below.

### First Modification

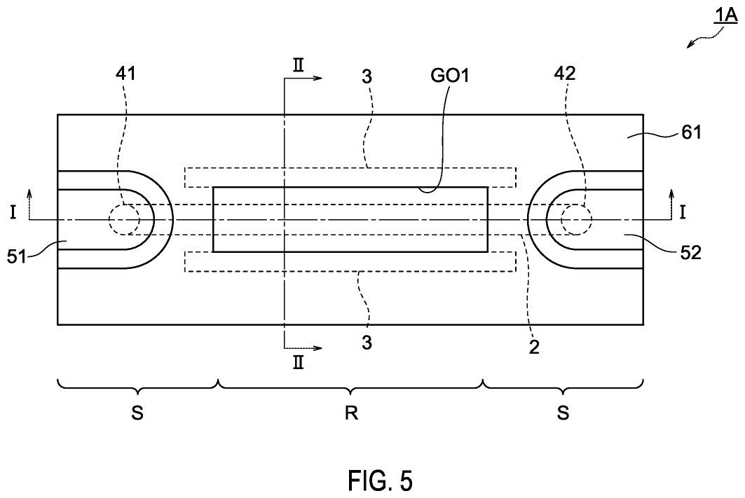

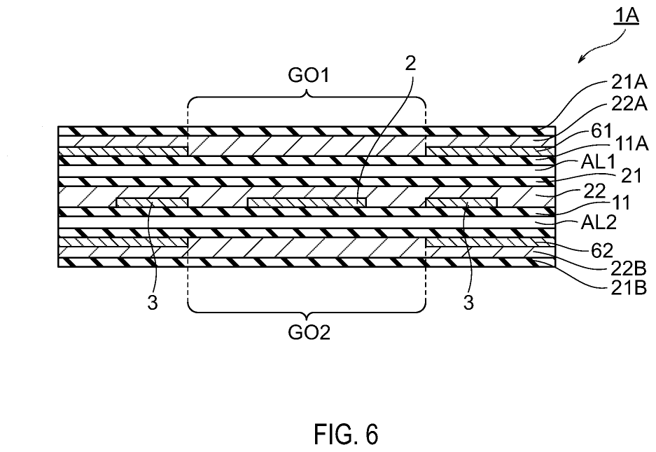

Next, a flexible printed wiring board 1A according to a first modification will be described with reference to FIGS. 5 and 6. FIG. 5 is a plan view of the flexible printed wiring board 1A. FIG. 6 is a cross-sectional view taken along line II-II in FIG. 5. The cross-sectional view taken along line I-I in FIG. 5 is the same as (2) of FIG. 1C.

As can be seen from FIGS. 5 and 6, in the present modification, the ground openings GO1 and GO2 are opened up to the side end portions of the guard ground wiring 3. Specifically, when the flexible printed wiring board 1A is viewed in the thickness direction, the ground opening GO1 is opened up to the side end portion of the guard ground wiring 3 on a side facing the signal line 2. Although not illustrated, the ground opening GO2 is similarly opened up to the side end portion of the guard ground wiring 3 on the side facing the signal line 2 when the flexible printed wiring board 1A is viewed in the thickness direction.

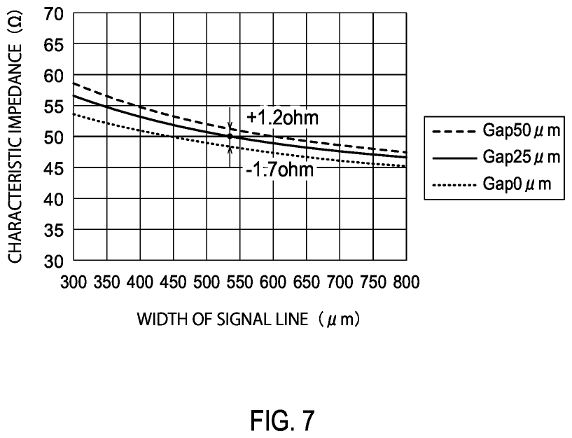

FIG. 7 illustrates a simulation result of a transmission characteristic (characteristic impedance) of the flexible printed wiring board 1A according to the present modification. Simulation conditions other than the opening widths of the ground openings GO1 and GO2 are the same as those in the above-described embodiment.

According to the simulation result, 50Ω, which is a target value of the characteristic impedance, is achieved when the thicknesses (Gap) of the air layers AL1 and AL2 are each 25 μm and the line width of the signal line 2 is between 500 to 550 μm. When Gap is 0 μm, the characteristic impedance at the line width is 48.3Ω (−1.7Ω from the target value), and when Gap is 50 μm, the characteristic impedance at the line width is 51.2Ω (+1.2Ω from the target value). As described above, according to the present modification, the variation in the characteristic impedance accompanying the change in the thickness of the air layers AL1 and AL2 can be kept within a range of ±10% of the target value.

The ground openings GO1 and GO2 may not be opened up to the side end portions of the guard ground wiring 3 over the entire region of the ground openings GO1 and GO2 in the longitudinal direction. That is, the ground openings GO1 and GO2 may be opened up to the side end portions of the guard ground wiring 3 in a partial region in the longitudinal direction.

### Second Modification

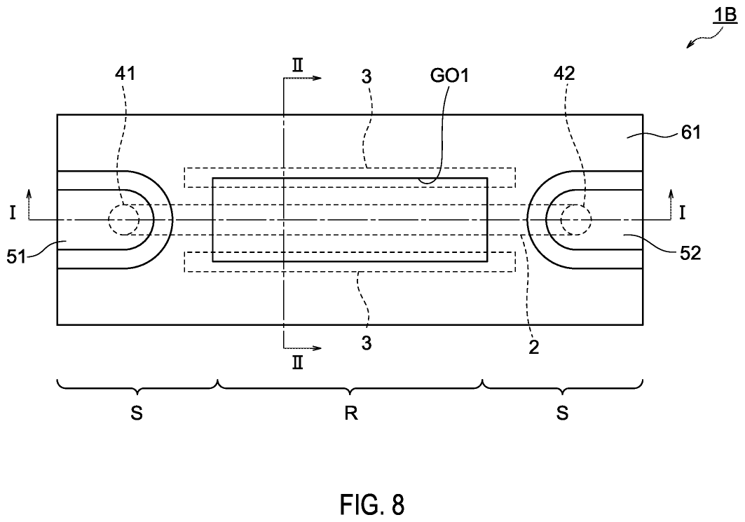

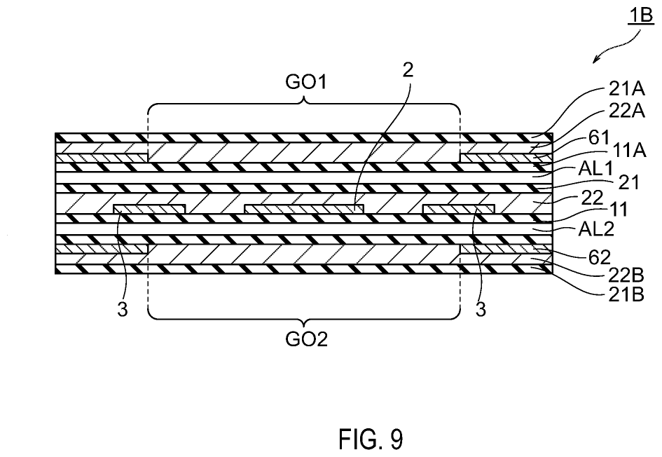

Next, a flexible printed wiring board 1B according to a second modification will be described with reference to FIGS. 8 and 9. FIG. 8 is a plan view of the flexible printed wiring board 1B. FIG. 9 is a cross-sectional view taken along line II-II in FIG. 8. The cross-sectional view taken along line I-I in FIG. 8 is the same as (2) of FIG. 1C.

As can be seen from FIGS. 8 and 9, in the present modification, the ground openings GO1 and GO2 are opened up to the middle of the guard ground wiring 3 (that is, to the outside from the side end portion of the guard ground wiring 3 in the width direction) when the flexible printed wiring board 1B is viewed in the thickness direction.

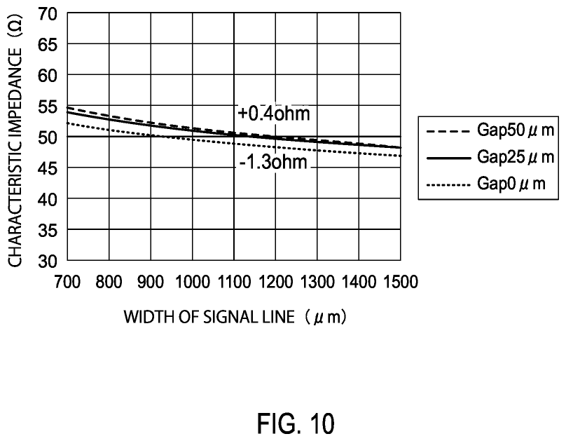

FIG. 10 illustrates a simulation result of a transmission characteristic (characteristic impedance) of the flexible printed wiring board 1B according to the present modification. Simulation conditions other than the opening widths of the ground openings GO1 and GO2 are the same as those in the embodiment.

According to the simulation result, 50Ω, which is a target value of the characteristic impedance, is achieved when the thicknesses (Gap) of the air layers AL1 and AL2 are each 25 μm and the line width of the signal line 2 is between 1050 to 1150 μm. When Gap is 0 μm, the characteristic impedance at the line width is 48.7Ω (−1.3Ω from the target value), and when Gap is 50 μm, the characteristic impedance at the line width is 50.4Ω (+0.4Ω from the target value). As described above, according to the present modification, it is possible to greatly reduce the variation in the characteristic impedance accompanying the change in the thickness of the air layers AL1 and AL2.

Note that the ground openings GO1 and GO2 may not be opened up to the middle of the guard ground wiring 3 over the entire region of the ground openings GO1 and GO2 in the longitudinal direction. That is, the ground openings GO1 and GO2 may be opened up to the middle of the guard ground wiring 3 in partial regions in the longitudinal direction.

As can be seen from the above embodiment and modifications, as the opening widths of the ground openings GO1 and GO2 increase, the variation in the characteristic impedance accompanying the change in the thickness of the air layers AL1 and AL2 tends to decrease. On the other hand, when the opening widths of the ground openings GO1 and GO2 are too large, the effect of the ground layer is weakened, and noise resistance is deteriorated. Therefore, for example, it is desirable that the ground openings GO1 and GO2 are opened up to positions 50 to 100 μm away from the side end portions of the signal line 2 in the width direction of the signal line 2.

Further, as in the second modification, since the ground openings GO1 and GO2 are opened up to the middle of the guard ground wiring 3 in the same layer as the signal line 2, it is possible to greatly suppress the variation in the characteristic impedance.

The types and thicknesses of the materials described in the above embodiment and modifications are merely examples, and may be the types and thicknesses of other materials.

In the above embodiment, the number of conductor layers is three, but the present invention is not limited thereto. That is, the flexible printed wiring board may be a flexible printed wiring board having two or four or more conductor layers as long as the flexible printed wiring board has a conductor layer including a signal line and a conductor layer including a ground layer.

In the above embodiment, the flexible printed wiring board has a so-called stripline structure in which the ground layers are provided on the layers on the upper and lower sides of the signal line, but the present invention is not limited thereto. That is, the flexible printed wiring board may have a so-called microstrip line structure in which the ground layer is provided only on one side of the signal line. In this case, for example, only one of the ground layer 61 and the ground layer 62 is provided on the flexible printed wiring board.

In the above embodiment, the ground opening is provided in the ground layer, but the present invention is not limited thereto, and the ground layer may be separated into two with the bent region R interposed therebetween. In this case, the ground layer includes a first ground layer and a second ground layer sandwiching the bent region.

In addition, according to the method for manufacturing a flexible printed wiring board, since the ground opening is formed in the process of forming the signal terminal, it is possible to manufacture a flexible printed wiring board in which the variation in the characteristic impedance is suppressed with respect to the bending of the bent region at low cost without adding a new process.

As described above, in the present disclosure, the ground layers 61 and 62 located above and below the signal line 2 are configured not to overlap at least a part of the signal line 2 in the bent region R when viewed in the thickness direction of the flexible printed wiring board 1. In other words, in the bent region R, when the flexible printed wiring board is viewed in the thickness direction, the ground layer is not provided in at least a part of the portion overlapping the signal line. As a result, even when the thicknesses of the air layers AL1 and AL2 change when the flexible printed wiring board is bent, the variation in the characteristic impedance can be suppressed. Further, in the flexible printed wiring board 1 according to the embodiment, the air layers AL1 and AL2 are provided between the signal line 2 and the ground layers 61 and 62 in the bent region R, and the air layers AL1 and AL2 penetrate the flexible printed wiring board 1 in the width direction. Therefore, the bending resistance (repeated bending property) of the flexible printed wiring board can be greatly improved.

### Comparative Example

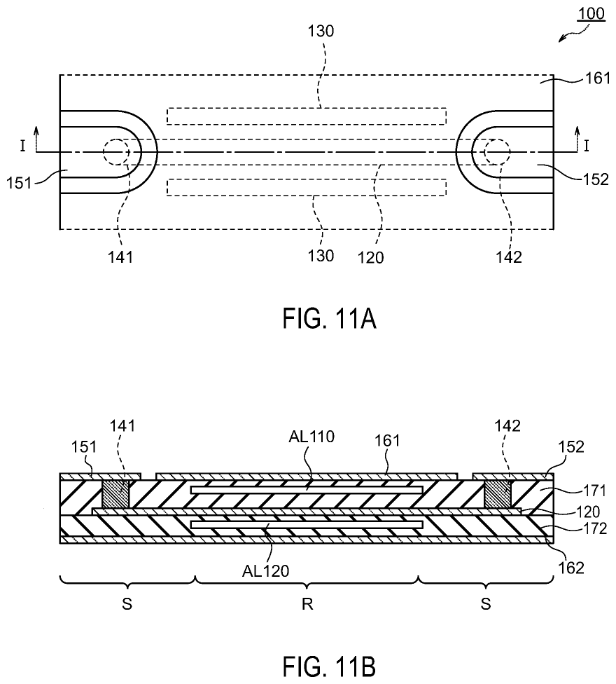

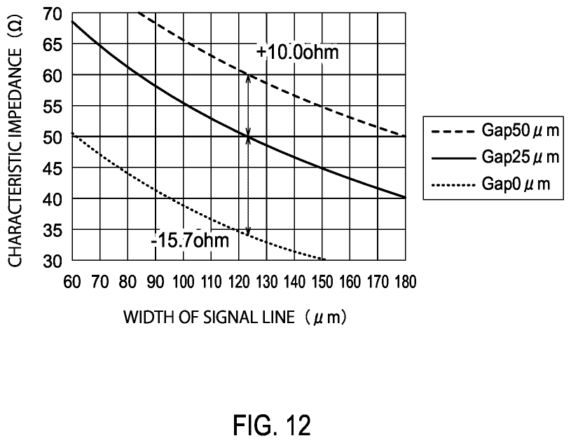

A comparative example will be described with reference to FIGS. 11A, 11B, and 12. FIG. 11A is a plan view of a flexible printed wiring board 100 according to the comparative example. FIG. 11B is a cross-sectional view taken along line I-I in FIG. 11A. FIG. 12 illustrates a simulation result of a transmission characteristic (characteristic impedance) of the flexible printed wiring board 100.

As illustrated in FIGS. 11A and 11B, the flexible printed wiring board 100 according to the comparative example includes a signal line 120, a guard ground wiring 130, vias 141 and 142, signal terminals 151 and 152, and ground layers 161 and 162. The ground layers 161 and 162 are provided so as to sandwich the signal line 120 via insulating layers 171 and 172 to form a stripline structure when the flexible printed wiring board 100 is viewed in the thickness direction.

The flexible printed wiring board 100 is provided with a bent region R and extension regions S in which the signal line 120 extends so as to sandwich the bent region R. In the bent region R, air layers (hollow portions) AL110 and AL120 are provided. The ground layers 161 and 162 are not provided with a ground opening, and are provided as a so-called solid pattern.

FIG. 12 is a graph illustrating a simulation result of a characteristic impedance of the flexible printed wiring board 100 according to the comparative example. A horizontal axis of the graph indicates a line width of the signal line 120, and a vertical axis indicates the characteristic impedance respectively. The thickness and relative dielectric constant of each layer used in the simulation are the same as those in Table 1 described above.

According to the simulation result, 50Ω, which is a target value of the characteristic impedance, is achieved when the thicknesses (Gap) of the air layers AL110 and AL120 are each 25 μm, and the line width of the signal line 120 is 120 to 130 μm. When Gap is 0 μm, the characteristic impedance at the line width is 34.3Ω (−15.7Ω from the target value), and when Gap is 50 μm, the characteristic impedance at the line width is 60Ω (+10.0Ω from the target value). As described above, in the case of the flexible printed wiring board according to the comparative example, the variation in the characteristic impedance at the time of bending is larger than that in the above-described embodiment and modifications, the change in the characteristic impedance is ±10% of the target value, and it is difficult to propagate a high-speed signal.

Although a person skilled in the art may be able to conceive additional effects and various modifications of the present invention based on the above description, aspects of the present invention are not limited to the above-described embodiment and modifications. Various additions, modifications, and partial deletions can be made without departing from the conceptual idea and spirit of the present invention derived from the contents defined in the claims and equivalents thereof.

1. A flexible printed wiring board having a bent region provided with an air layer, the flexible printed wiring board comprising:
a signal line passing through the bent region; and a ground layer provided in a layer different from the signal line via an insulating layer, wherein
the ground layer is not provided in at least a part of a portion overlapping the signal line in the bent region when the flexible printed wiring board is viewed in a thickness direction.

2. The flexible printed wiring board according to claim 1, wherein the ground layer is provided with a ground opening at least partially overlapping the signal line when the flexible printed wiring board is viewed in the thickness direction.

3. The flexible printed wiring board according to claim 2, wherein a width of the ground opening is equal to a width of the signal line.

4. The flexible printed wiring board according to claim 2, further comprising:
guard ground wirings provided so as to sandwich the signal line, wherein
the ground opening is opened up to a side end portion of the guard ground wiring on a side facing the signal line when the flexible printed wiring board is viewed in the thickness direction.

5. The flexible printed wiring board according to claim 2, further comprising:
guard ground wirings provided so as to sandwich the signal line, wherein
the ground opening is opened up to a middle of the guard ground wiring when the flexible printed wiring board is viewed in the thickness direction.

6. The flexible printed wiring board according to claim 2, wherein
a plurality of the signal lines are provided so as to run in parallel, and
the ground opening is opened such that at least a part of the ground opening overlaps the plurality of signal lines when the flexible printed wiring board is viewed in the thickness direction.

7. The flexible printed wiring board according to claim 2, wherein the ground opening is opened up to a position 50 to 100 μm away from the side end portion of the signal line in the width direction of the signal line.

8. The flexible printed wiring board according to claim 1, wherein the ground layer has a first ground layer and a second ground layer sandwiching the bent region.

9. A method for manufacturing a flexible printed wiring board, the method comprising:
preparing a first single-sided metal clad laminated board having a first base film and a first metal foil provided on one main surface of the first base film;
patterning the first metal foil of the first single-sided metal clad laminated board to form a signal line;
preparing a cover lay having a cover film and a first adhesive layer provided on one main surface of the cover film, and bonding the cover lay to the first base film such that the first adhesive layer buries the signal line;
temporarily attaching a first bonding sheet provided with a first through region onto the cover film, and temporarily attaching a second bonding sheet provided with a second through region onto the first base film;
preparing a second single-sided metal clad laminated board having a second base film and a second metal foil provided on one main surface of the second base film, and bonding the second single-sided metal clad laminated board to the first bonding sheet such that the second base film is in contact with the first bonding sheet;
preparing a third single-sided metal clad laminated board having a third base film and a third metal foil provided on one main surface of the third base film, and bonding the third single-sided metal clad laminated board to the second bonding sheet such that the third base film is in contact with the second bonding sheet;
forming a conformal mask for laser processing on the second metal foil;
irradiating the conformal mask with laser light to form a conductive hole in which the signal line is exposed on a bottom surface;
performing plating processing on the conductive hole to form a via electrically coupling the signal line and the second metal foil; and
patterning the second metal foil to form a signal terminal electrically coupled to the via and a ground layer that is not provided in at least a part of a portion overlapping the signal line as viewed in a thickness direction in the first through region.

10. The method for manufacturing a flexible printed wiring board according to claim 9, further comprising: patterning the third metal foil to form a second ground layer that is not provided in at least the part of the portion overlapping the signal line as viewed in the thickness direction in the second through region.
